(19) United States
(12) Patent Application Publication
(10) Pub. No.: US 2018/0321765 A1
(43) Pub. Date: Nov. 8, 2018

(54) CAPACITIVE TOUCH PANEL

(71) Applicant: Raydium Semiconductor Corporation, Hsinchu (TW)

(72) Inventors: Chang-Ching CHIANG, Taichung City (TW); Kun-Pei LEE, Miaoli County (TW)

(21) Appl. No.: 15/964,364

(22) Filed: Apr. 27, 2018

Related U.S. Application Data
(60) Provisional application No. 62/500,594, filed on May 3, 2017.

(51) Int. Cl. G06F 3/044; G06F 3/041; H01L 27/32

(52) U.S. Cl. CPC G06F 3/044; G06F 3/0412; H01L 27/3265; H01L 27/323; G06F 3/0416

(57) ABSTRACT

A capacitive touch panel is disclosed. The capacitive touch panel includes a plurality of pixels. A laminated structure of each pixel includes a substrate, a display layer, a thin-film encapsulation layer and a conductive layer from bottom to top. The display layer is disposed above the substrate. The thin-film encapsulation layer opposite to the substrate is disposed above the display layer. The thin-film encapsulation layer includes alternately stacked organic material layer and inorganic material layer. The conductive layer is disposed above the display layer. The conductive layer is electrically connected to a contact on the display layer through a via formed in the thin-film encapsulation layer.

### BACKGROUND OF THE INVENTION

### 1. Field of the Invention

The invention relates to a display; in particular, to a capacitive touch panel.

### 2. Description of the Prior Art

In general, compared with the technology of plugging the external touch-sensing module on the display module, the touch-sensing electrode disposed on the encapsulation layer of the display module through the on-cell technology can effectively reduce the module thickness.

Since the traces of the touch sensing layer and the traces of the display layer are disposed in different layers respectively, it is conventionally to use different flexible circuit boards (FPCs) to couple the touch sensing layer and the display layer respectively, or to use a flexible circuit board divided into two areas bonding to the touch sensing layer and the display layer respectively. However, the above-mentioned methods not only increase the cost of the FPCs, but also require separate bonding processes, which may also lead to a decrease of manufacturing yield. The above problems need to be overcome.

### SUMMARY OF THE INVENTION

Therefore, the invention provides a capacitive touch panel to overcome the above-mentioned problems in the prior art.

An embodiment of the invention is a capacitive touch panel. In this embodiment, the capacitive touch panel includes a plurality of pixels. A laminated structure of each pixel includes a substrate, a display layer, a thin-film encapsulation layer and a conductive layer from bottom to top. The display layer is disposed above the substrate. The thin-film encapsulation layer opposite to the substrate is disposed above the display layer. The thin-film encapsulation layer includes alternately stacked organic material layer and inorganic material layer. The conductive layer is disposed above the display layer. The conductive layer is electrically connected to a contact on the display layer through a via formed in the thin-film encapsulation layer.

In an embodiment, the thin-film encapsulation layer is formed by alternately stacking at least one the organic material layer and at least one the inorganic material layer through a thin-film encapsulation technology.

In an embodiment, the display layer includes a display area and a non-display area, the contact is formed in the non-display area and a position of the via formed in the thin-film encapsulation layer corresponds to the non-display area.

In an embodiment, the conductive layer includes a touch sensing electrode suitable for mutual-capacitive touch sensing technology or self-capacitive touch sensing technology.

In an embodiment, the conductive layer further includes a trace coupled to the touch sensing electrode, and the touch sensing electrode is electrically connected to the contact on the display layer through the trace and the via in order.

In an embodiment, the display layer includes an organic light-emitting diode (OLED) laminated structure.

In an embodiment, the contact on the display layer is coupled to a driving circuit and the driving circuit is a touch driving circuit or a touch and display driving integrated circuit.

In an embodiment, the conductive layer is disposed above the thin-film encapsulation layer.

In an embodiment, the conductive layer is disposed in the thin-film encapsulation layer.

In an embodiment, the conductive layer is located between the alternately stacked organic material layer and inorganic material layer.

In an embodiment, the conductive layer is filled into the via to be electrically connected to the contact on the display layer.

In an embodiment, the capacitive touch panel further includes a conductive filling layer. The conductive filling layer is filled into the via and used for electrically connecting the conductive layer and the contact on the display layer.

In an embodiment, after the conductive filling layer is filled into the via, the conductive layer is formed and electrically connected to the conductive filling layer.

In an embodiment, a part of the conductive layer is disposed above the conductive filling layer and electrically connected to the conductive filling layer.

In an embodiment, after the conductive layer is formed, the conductive filling layer is filled into the via and electrically connected to the conductive layer.

In an embodiment, a part of the conductive layer is disposed under the conductive filling layer and electrically connected to the conductive filling layer.

In an embodiment, the capacitive touch panel further includes another conductive layer disposed above the display layer

In an embodiment, the conductive layer and the another conductive layer are both disposed in the thin-film encapsulation layer and insulated from each other.

In an embodiment, the conductive layer and the another conductive layer are both disposed above the thin-film encapsulation layer and insulated from each other.

In an embodiment, the conductive layer is electrically connected through a bridge structure, and the bridge structure and the another conductive layer are insulated from each other.

Compared to the prior arts, the capacitive touch panel of the invention can be used in any self-luminous display (e.g., the OLED display, but not limited to this) having on-cell laminated structure and using thin-film encapsulation technology and suitable for mutual-capacitive touch sensing technology and self-capacitive touch sensing technology. Since the touch sensing electrode disposed on the thin-film encapsulation layer or in the thin-film encapsulation layer can be electrically connected to the contact on the display layer through the via formed in the non-display area of the thin-film encapsulation layer, the capacitive touch panel of the invention can decrease the number of the FPCs and the times of the bonding processes through its innovative laminated structure and layout to effectively reduce cost and enhance the manufacturing yield.

The advantage and spirit of the invention may be understood by the following detailed descriptions together with the appended drawings.

### BRIEF DESCRIPTION OF THE APPENDED DRAWINGS

FIG. 1 illustrates a schematic diagram of the laminated structure of the capacitive touch panel in an embodiment of the invention.

FIG. 2 illustrates a schematic diagram of the conductive layer disposed above the thin-film encapsulation layer.

FIG. 3 illustrates a schematic diagram of the conductive layer disposed in the thin-film encapsulation layer.

FIG. 4 illustrates a schematic diagram of two conductive layers formed in the thin-film encapsulation layer and insulated from each other.

FIG. 5 illustrates a schematic diagram of the conductive layer formed earlier than the conductive filling layer filled into the via.

FIG. 6 illustrates a schematic diagram of the conductive layer formed later than the conductive filling layer filled into the via.

### DETAILED DESCRIPTION OF THE INVENTION

A preferred embodiment of the invention is a capacitive touch panel. In practical applications, the capacitive touch panel can be used in any self-luminous display (e.g., the OLED display, but not limited to this) having on-cell laminated structure and using thin-film encapsulation technology and suitable for mutual-capacitive touch sensing technology and self-capacitive touch sensing technology. The touch sensing layer of the capacitive touch panel is formed by a conductive material. The touch sensing layer can be disposed on the thin-film encapsulation layer or in the thin-film encapsulation layer. The thin-film encapsulation layer is formed by alternately stacking at least one the organic material layer and at least one the inorganic material layer through a thin-film encapsulation technology.

In this embodiment, the capacitive touch panel includes a plurality of pixels. A laminated structure of each pixel includes a substrate a display layer, a thin-film encapsulation layer and a conductive layer from bottom to top. The display layer is disposed above the substrate. The thin-film encapsulation layer opposite to the substrate is disposed above the display layer. The thin-film encapsulation layer includes alternately stacked organic material layer and inorganic material layer. The conductive layer is disposed above the display layer. The conductive layer is electrically connected to a contact on the display layer through a via formed in the thin-film encapsulation layer.

Please refer to FIG. 1. FIG. 1 illustrates a schematic diagram of the laminated structure of the capacitive touch panel in this embodiment. As shown in FIG. 1, the laminated structure 1 of the on-cell capacitive touch panel includes a flexible printed circuit FPC, a substrate SUB, a display layer DL, a thin-film encapsulation layer TFE and a conductive layer CL. The flexible printed circuit FPC is bonded to the substrate SUB. The display layer DL is disposed above the substrate SUB; the thin-film encapsulation layer TFE is disposed above the display layer DL; the conductive layer CL is disposed above the thin-film encapsulation layer TFE.

The display layer DL includes a display area AA and a non-display area BA. The thin-film encapsulation layer TFE is formed by alternately stacking at least one the organic material layer and at least one the inorganic material layer through a thin-film encapsulation technology. A via VIA is disposed on the thin-film encapsulation layer TFE corresponding to the non-display area BA of the display layer DL. A contact CT is disposed in the non-display area BA of the display layer DL. A display driving integrated circuit DIC is also disposed in the non-display area BA of the display layer DL. The display driving integrated circuit DIC is coupled to the display area AA through traces WD. The conductive layer CL includes a touch sensing electrode TS and its trace TR. The touch sensing electrode TS is suitable for mutual-capacitive touch sensing technology and self-capacitive touch sensing technology.

In this embodiment, the touch sensing electrode TS is coupled to the trace TR and the trace TR is electrically connected to a contact CT formed on the non-display area BA of the display layer DL through the via VIA. The contact CT can be coupled to a touch driving integrated circuit TIC through a trace WT. Thus, the touch sensing electrode TS can be electrically connected to the touch driving integrated circuit TIC through the trace TR, the via VIA, the contact CT and the trace WT in order; a touch driving signal outputted by the touch driving integrated circuit TIC can be transmitted to the touch sensing electrode TS through the trace WT, the contact CT, the via VIA and the trace TR in order.

In practical applications, the touch driving integrated circuit TIC can be disposed on the flexible printed circuit FPC, and the display layer DL can include an OLED laminated structure, but not limited to this.

It should be noted that the conductive layer CL is disposed above the thin-film encapsulation layer TFE in this embodiment; however, in fact, the conductive layer CL of the invention can be disposed in the thin-film encapsulation layer TFE. And, the number of the conductive layer CL is not limited to one layer; it can be multiple conductive layers insulated from each other.

In addition, if the touch driving integrated circuit TIC and the display driving integrated circuit DIC are integrated into a touch and display driving integrated circuit disposed on the non-display area BA of the display layer DL, for example, a touch and display driver integration (TDDI) IC. Since the touch sensing electrode TS is electrically connected to the contact CT formed on the non-display area BA of the display layer DL, it can be further electrically connected to the touch and display driving integrated circuit which is also formed on the non-display area BA of the display layer DL.

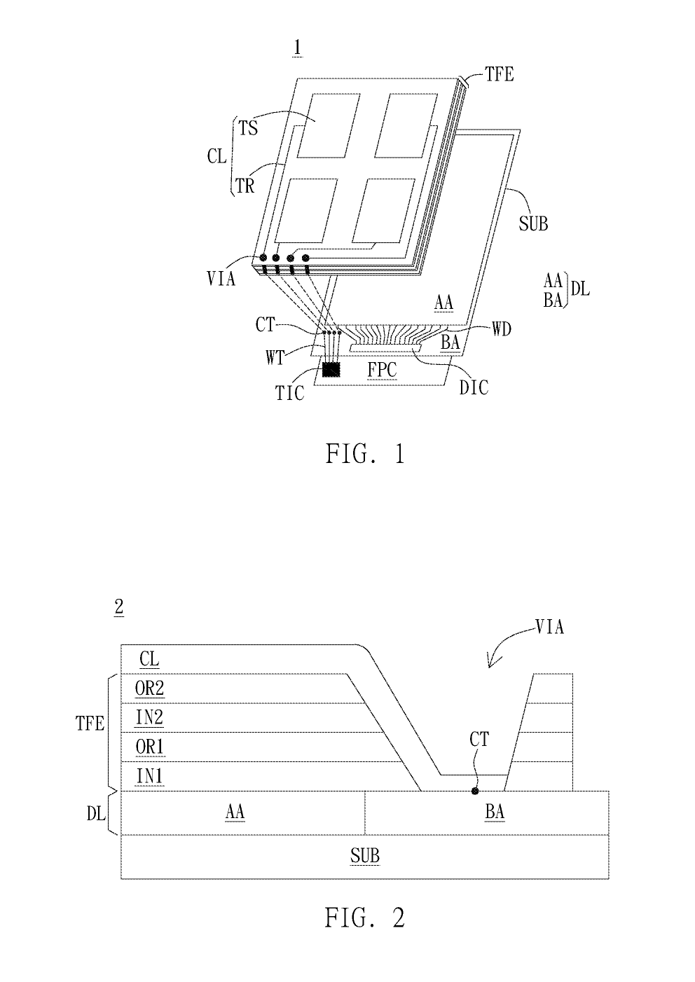

Please refer to FIG. 2. FIG. 2 illustrates a schematic diagram of the conductive layer CL disposed above the thin-film encapsulation layer TFE. As shown in FIG. 2, the laminated structure 2 of the on-cell capacitive touch panel includes a substrate SUB, a display layer DL, a thin-film encapsulation layer TFE and a conductive layer CL from bottom to top. The display layer DL is disposed above the substrate SUB; the thin-film encapsulation layer TFE is disposed above the display layer DL; the conductive layer CL is disposed above the thin-film encapsulation layer TFE.

The display layer DL includes a display area AA and a non-display area BA. The thin-film encapsulation layer TFE includes an inorganic material layer IN1, an organic material layer OR1, an inorganic material layer IN2 and an organic material layer OR2 from bottom to top. A position of a via VIA formed in the thin-film encapsulation layer TFE corresponds to the non-display area BA of the display layer DL. The via VIA passes through the organic material layer OR2, the inorganic material layer IN2, the organic material layer OR1 and the inorganic material layer IN1 in order from top to bottom and reaches the non-display area BA of the display layer DL. The conductive layer CL formed above the thin-film encapsulation layer TFE can be filled into the via VIA and extended to the non-display area BA of the display layer DL.

In this embodiment, a contact CT is formed in the non-display area BA of the display layer DL; therefore, the conductive layer CL formed above the thin-film encapsulation layer TFE can be electrically connected to the contact CT formed in the non-display area BA of the display layer DL through the via VIA.

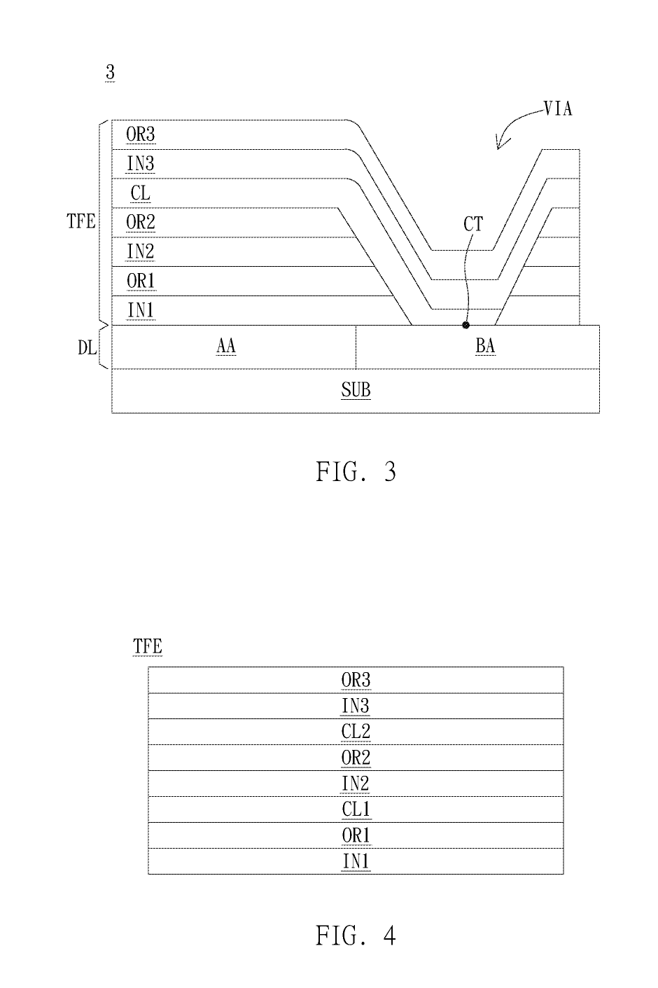

Please refer to FIG. 3. FIG. 3 illustrates a schematic diagram of the conductive layer CL disposed in the thin-film encapsulation layer TFE. As shown in FIG. 3, the laminated structure 3 of the on-cell capacitive touch panel includes a substrate SUB, a display layer DL, a thin-film encapsulation layer TFE and a conductive layer CL from bottom to top. The display layer DL is disposed above the substrate SUB; the thin-film encapsulation layer TFE is disposed above the display layer DL; the conductive layer CL is disposed in the thin-film encapsulation layer TFE.

The display layer DL includes a display area AA and a non-display area BA. Since the conductive layer CL is disposed in the thin-film encapsulation layer TFE, the thin-film encapsulation layer TFE can include an inorganic material layer IN1, an organic material layer OR1, an inorganic material layer IN2, an organic material layer OR2, the conductive layer CL, an inorganic material layer IN3 and an organic material layer OR3 from bottom to top. A position of a via VIA formed in the thin-film encapsulation layer TFE corresponds to the non-display area BA of the display layer DL. The via VIA passes through the organic material layer OR2, the inorganic material layer IN2, the organic material layer OR1 and the inorganic material layer IN1 in order from top to bottom and reaches the non-display area BA of the display layer DL. Then, the inorganic material layer IN3 and the organic material layer OR3 are formed above the conductive layer CL in order.

In this embodiment, a contact CT is formed in the non-display area BA of the display layer DL; therefore, the conductive layer CL formed in the thin-film encapsulation layer TFE can be electrically connected to the contact CT formed in the non-display area BA of the display layer DL through the via VIA.

Please refer to FIG. 4. FIG. 4 illustrates a schematic diagram of two conductive layers CL1˜CL2 formed in the thin-film encapsulation layer TFE and insulated from each other. As shown in FIG. 4, the thin-film encapsulation layer TFE can include an inorganic material layer IN1, an organic material layer OR1, a conductive layer CL1, an inorganic material layer IN2, an organic material layer OR2, a conductive layer CL2, an inorganic material layer IN3 and an organic material layer OR3 from bottom to top. The conductive layers CL1 and CL2 are not connected and insulated from each other through the inorganic material layer IN2 and the organic material layer OR2 disposed between the conductive layers CL1 and CL2. In practical applications, the number and the position of the conductive layer can be determined based on practical needs and not limited to this.

It should be noted that in practical applications, except the above-mentioned laminated structures, two conductive layers can be both disposed above the thin-film encapsulation layer TFE and insulated from each other. One of the two conductive layers can be electrically connected through a bridge structure, and the bridge structure and the other conductive layer are insulated from each other, but not limited to this.

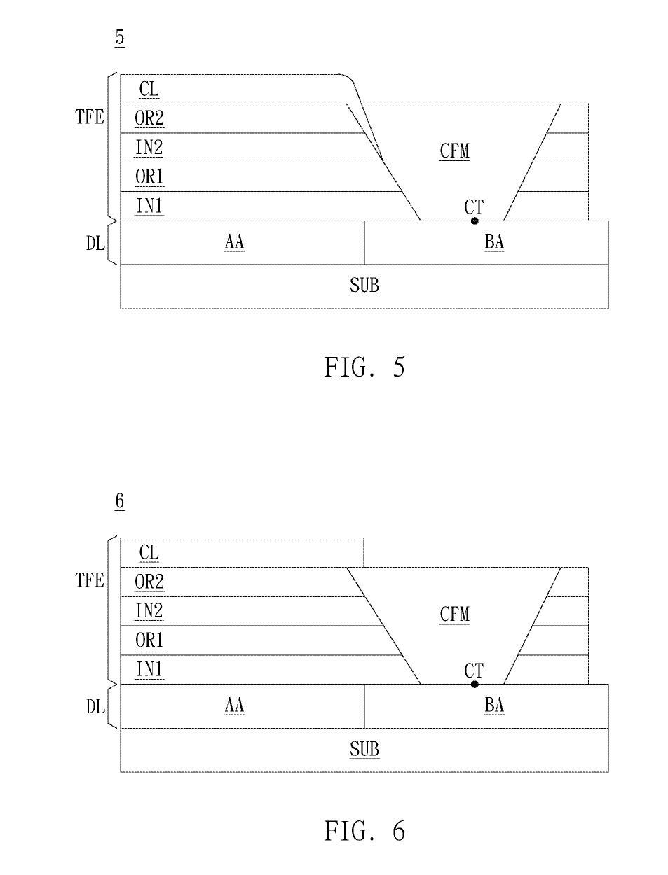

Please refer to FIG. 5. FIG. 5 illustrates a schematic diagram of the conductive layer CL formed earlier than the conductive filling layer CFM filled into the via VIA. As shown in FIG. 5, the laminated structure 5 of the on-cell capacitive touch panel includes a substrate SUB, a display layer DL, a thin-film encapsulation layer TFE and a conductive layer CL from bottom to top. The display layer DL is disposed above the substrate SUB; the thin-film encapsulation layer TFE is disposed above the display layer DL; the conductive layer CL is disposed above the thin-film encapsulation layer TFE.

The display layer DL includes a display area AA and a non-display area BA. The thin-film encapsulation layer TFE includes an inorganic material layer IN1, an organic material layer OR1, an inorganic material layer IN2 and an organic material layer OR2 from bottom to top. A position of a via VIA formed in the thin-film encapsulation layer TFE corresponds to the non-display area BA of the display layer DL. The via VIA passes through the organic material layer OR2, the inorganic material layer IN2, the organic material layer OR1 and the inorganic material layer IN1 in order from top to bottom and reaches the non-display area BA of the display layer DL.

It should be noted that only a part of the conductive layer CL formed above the thin-film encapsulation layer TFE is filled into the via VIA, but the conductive layer CL is not extended downward to the non-display area BA of the display layer DL. Then, a conductive filling material can be used to fill into the via VIA to form a conductive filling layer CFM. Since a part of the conductive layer CL is filled into the via VIA, as shown in FIG. 5, the conductive filling layer CFM formed later than the conductive layer CL will cover the part of the conductive layer CL filled in the via VIA. By doing so, the conductive layer CL formed above the thin-film encapsulation layer TFE can be electrically connected to the contact CT formed in the non-display area BA of the display layer DL through the conductive filling layer CFM filled in the via VIA.

Please refer to FIG. 6. FIG. 6 illustrates a schematic diagram of the conductive layer CL formed later than the conductive filling layer CFM filled into the via VIA. As shown in FIG. 6, the laminated structure 6 of the on-cell capacitive touch panel includes a substrate SUB, a display layer DL, a thin-film encapsulation layer TFE and a conductive layer CL from bottom to top. The display layer DL is disposed above the substrate SUB; the thin-film encapsulation layer TFE is disposed above the display layer DL; the conductive layer CL is disposed above the thin-film encapsulation layer TFE.

The display layer DL includes a display area AA and a non-display area BA. The thin-film encapsulation layer TFE includes an inorganic material layer IN1, an organic material layer OR1, an inorganic material layer IN2 and an organic material layer OR2 from bottom to top. A position of a via VIA formed in the thin-film encapsulation layer TFE corresponds to the non-display area BA of the display layer DL. The via VIA passes through the organic material layer OR2, the inorganic material layer IN2, the organic material layer OR1 and the inorganic material layer IN1 in order from top to bottom and reaches the non-display area BA of the display layer DL.

It should be noted that before the conductive layer CL is formed above the thin-film encapsulation layer TFE, a conductive filling material can be used to fill into the via VIA to form a conductive filling layer CFM. Then, the conductive layer CL is formed above the thin-film encapsulation layer TFE. At this time, a part of the conductive layer CL will cover the conductive filling layer CFM formed earlier than the conductive layer CL. By doing so, the conductive layer CL formed above the thin-film encapsulation layer TFE can be electrically connected to the contact CT formed in the non-display area BA of the display layer DL through the conductive filling layer CFM filled in the via VIA.

Compared to the prior arts, the capacitive touch panel of the invention can be used in any self-luminous display (e.g., the OLED display, but not limited to this) having on-cell laminated structure and using thin-film encapsulation technology and suitable for mutual-capacitive touch sensing technology and self-capacitive touch sensing technology. Since the touch sensing electrode disposed on the thin-film encapsulation layer or in the thin-film encapsulation layer can be electrically connected to the contact on the display layer through the via formed in the non-display area of the thin-film encapsulation layer, the capacitive touch panel of the invention can decrease the number of the FPCs and the times of the bonding processes through its innovative laminated structure and layout to effectively reduce cost and enhance the manufacturing yield.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A capacitive touch panel, comprising:
a plurality of pixels, a laminated structure of each pixel from bottom to top comprising:
a substrate;
a display layer disposed above the substrate;
a thin-film encapsulation layer, opposite to the substrate and disposed above the display layer, comprising alternately stacked organic material layer and inorganic material layer; and
a conductive layer disposed above the display layer;
wherein the conductive layer is electrically connected to a contact on the display layer through a via formed in the thin-film encapsulation layer.

2. The capacitive touch panel of claim 1, wherein the thin-film encapsulation layer is formed by alternately stacking at least one the organic material layer and at least one the inorganic material layer through a thin-film encapsulation technology.

3. The capacitive touch panel of claim 1, wherein the display layer comprises a display area and a non-display area, the contact is formed in the non-display area and a position of the via formed in the thin-film encapsulation layer corresponds to the non-display area.

4. The capacitive touch panel of claim 1, wherein the conductive layer comprises a touch sensing electrode suitable for mutual-capacitive touch sensing technology or self-capacitive touch sensing technology.

5. The capacitive touch panel of claim 4, wherein the conductive layer further comprises a trace coupled to the touch sensing electrode, and the touch sensing electrode is electrically connected to the contact on the display layer through the trace and the via in order.

6. The capacitive touch panel of claim 1, wherein the display layer comprises an organic light-emitting diode (OLED) laminated structure.

7. The capacitive touch panel of claim 1, wherein the contact on the display layer is coupled to a driving circuit and the driving circuit is a touch driving circuit or a touch and display driving integrated circuit.

8. The capacitive touch panel of claim 1, wherein the conductive layer is disposed above the thin-film encapsulation layer.

9. The capacitive touch panel of claim 1, wherein the conductive layer is disposed in the thin-film encapsulation layer.

10. The capacitive touch panel of claim 9, wherein the conductive layer is located between the alternately stacked organic material layer and inorganic material layer.

11. The capacitive touch panel of claim 1, wherein the conductive layer is filled into the via to be electrically connected to the contact on the display layer.

12. The capacitive touch panel of claim 1, further comprising:
a conductive filling layer, filled into the via, for electrically connecting the conductive layer and the contact on the display layer.

13. The capacitive touch panel of claim 12, wherein after the conductive filling layer is filled into the via, the conductive layer is formed and electrically connected to the conductive filling layer.

14. The capacitive touch panel of claim 13, wherein a part of the conductive layer is disposed above the conductive filling layer and electrically connected to the conductive filling layer.

15. The capacitive touch panel of claim 13, wherein after the conductive layer is formed, the conductive filling layer is filled into the via and electrically connected to the conductive layer.

16. The capacitive touch panel of claim 15, wherein a part of the conductive layer is disposed under the conductive filling layer and electrically connected to the conductive filling layer.

17. The capacitive touch panel of claim 1, further comprising:
another conductive layer disposed above the display layer.

18. The capacitive touch panel of claim 17, wherein the conductive layer and the another conductive layer are both disposed in the thin-film encapsulation layer and insulated from each other.

19. The capacitive touch panel of claim 17, wherein the conductive layer and the another conductive layer are both disposed above the thin-film encapsulation layer and insulated from each other.

20. The capacitive touch panel of claim 19, wherein the conductive layer is electrically connected through a bridge structure, and the bridge structure and the another conductive layer are insulated from each other.
